(19) United States
(12) Patent Application Publication
(10) Pub. No.: US 2007/0231748 A1
(43) Pub. Date: Oct. 4, 2007

(54) Patterning trenches in a photoresist layer with tight end-to-end separation

(76) Inventors: Swaminathan Sivakumar, Portland, OR (US); Charles Wallace, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/393,096

(22) Filed: Mar. 29, 2006

(51) Int. Cl. G03F 7/26

(52) U.S. Cl. 430/313; 430/311

(57) ABSTRACT

A method for forming two trenches with tight end-to-end spacing in a dielectric layer begins with providing a substrate having a dielectric layer. A hard-mask layer is deposited on the dielectric layer and a first photoresist layer is deposited on the hard-mask layer. The first photoresist layer is patterned to form an extended trench in the first photoresist layer. The hard-mask layer is then etched using the first photoresist layer as a mask to form an extended trench in the hard-mask layer. Next, a second photoresist layer is deposited on the hard-mask layer and patterned to form a resist line that intersects the extended trench. The resist line divides the extended trench into two separate trenches. The dielectric layer is then etched using the hard-mask layer and the resist line as a mask, thereby forming two trenches in the dielectric layer with end-to-end separation that corresponds to the resist line width.

### BACKGROUND

As integrated circuit dimensions continue to decrease, the circuit density within an integrated circuit chip must increase. A key design rule that affects circuit density is the ability to form two trenches in close proximity to one another. In particular, there is a need to form trenches that have tight end-to-end separation. Such trenches must first be patterned in a photoresist layer and this pattern may then be transferred to a dielectric layer of an integrated circuit. The trenches may then be used in a damascene metallization process.

Unfortunately, limitations with current photolithography processes prevent trenches from being formed with tight end-to-end spacing. For instance, FIG. 1 illustrates a portion of a mask pattern 100 for two trenches 102 that are aligned end-to-end. The end-to-end separation 104 on the mask is small and the ends of the trenches 102 are squared off. When this mask pattern 100 is used to expose a photoresist layer, however, resolution limitations in conventional photolithography systems transfer a pattern to the photoresist material that does not match the mask 100. FIG. 2 illustrates how the pattern on the mask 100 is translated onto a photoresist layer 200. As shown, two trenches 202 are formed in the photoresist layer 200 and an end-to-end separation 204 of the trenches 202 is greater than the end-to-end separation 104 on the mask pattern 100. In addition, the ends of the trenches 202 are rounded rather than squared.

In some current systems, an Optical Proximity correction technique may be used to improve the end-to-end separation. Unfortunately, it is still very difficult to achieve the aggressive end-to-end configuration that is desired. The current inability to support a tight end-to-end separation has significant impact on circuit density. Accordingly, improved methods are needed to overcome the resolution limitations of current photolithography systems to improve end-to-end separation of trenches.

### BRIEF DESCRIPTION OF THE DRAWINGS

FIG. 1 illustrates a mask pattern that contains patterns for two trenches having a desired end-to-end separation.

FIG. 2 illustrates the result of patterning a photoresist layer using the mask pattern of FIG. 1 and a conventional photolithography system.

FIG. 3 is a method of patterning trenches in a photoresist layer using a dual exposure method in accordance with an implementation of the invention.

FIGS. 4A to 4J illustrate structures that are formed when carrying out the method of FIG. 3.

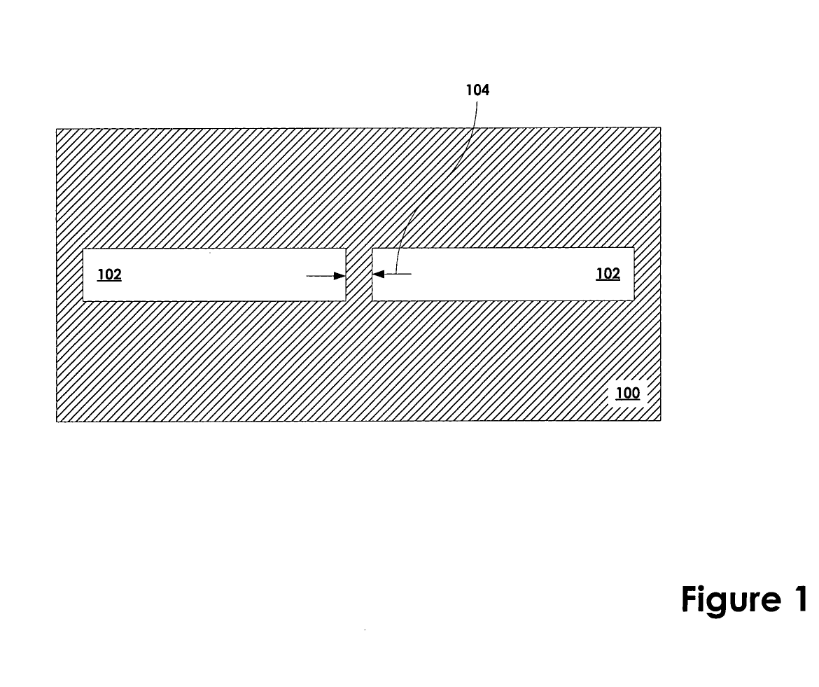

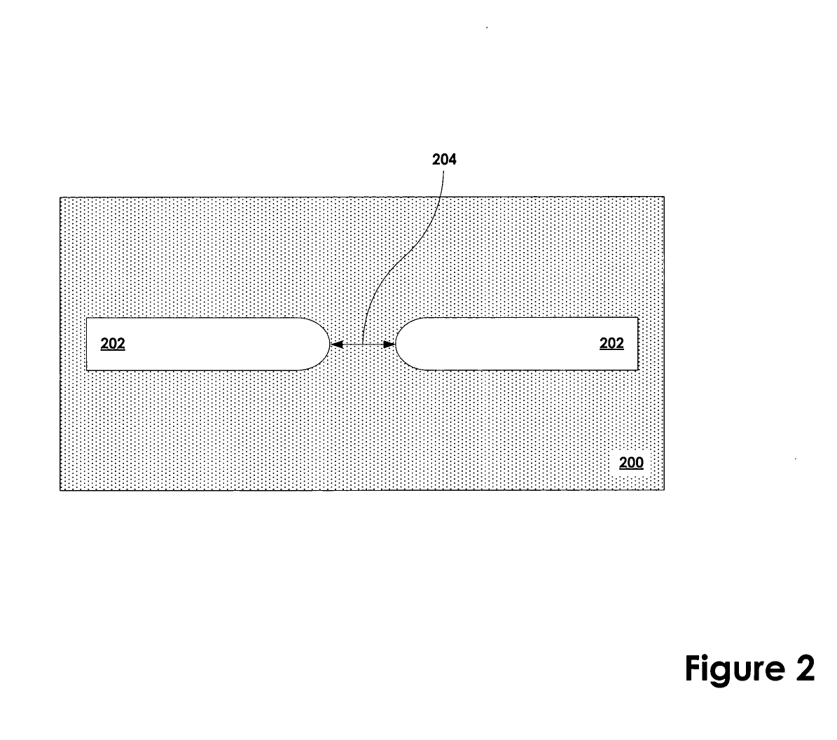

### DETAILED DESCRIPTION

Described herein are methods of forming trenches in photoresist layers with tight end-to-end spacing. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide methods for forming trenches in a dielectric layer with relatively tight end-to-end spacing that cannot be achieved using conventional photolithography processes. In implementations of the invention, a dual-patterning process is used to form the trenches. The first patterning process etches an extended trench into a hard-mask layer that is formed on the dielectric layer. The second patterning process forms a resist line across the extended trench to separate the extended trench into two trenches with tight end-to-end spacing. This pattern is then transferred into the dielectric layer using conventional etching processes.

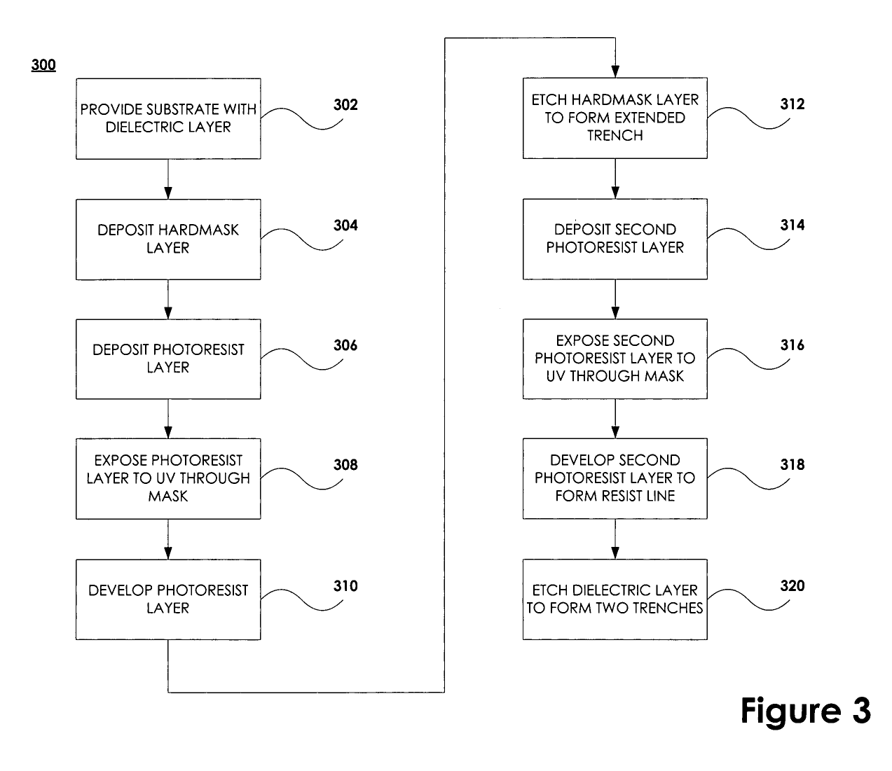

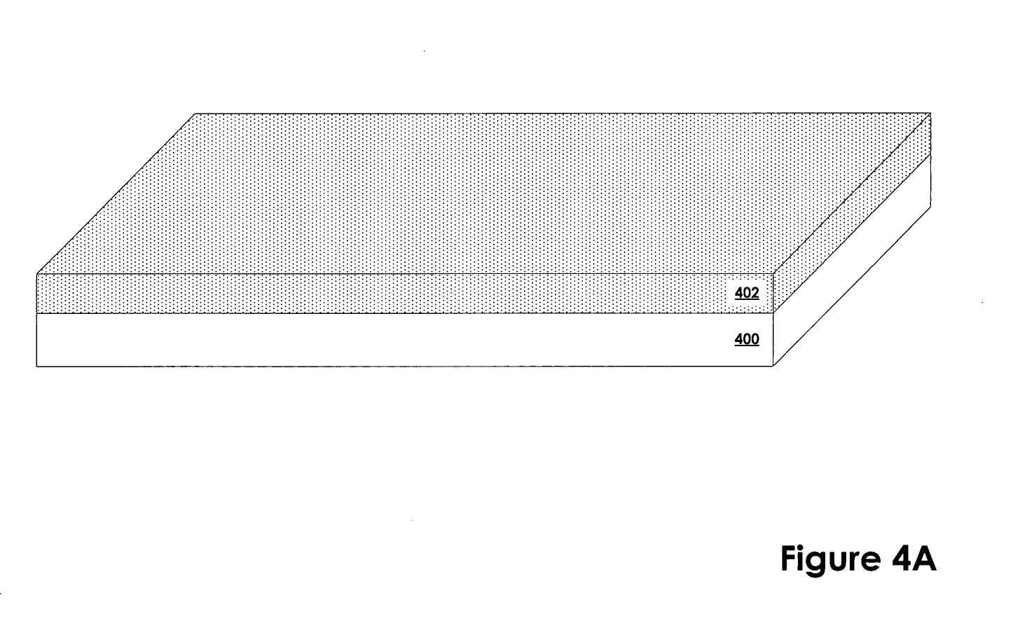

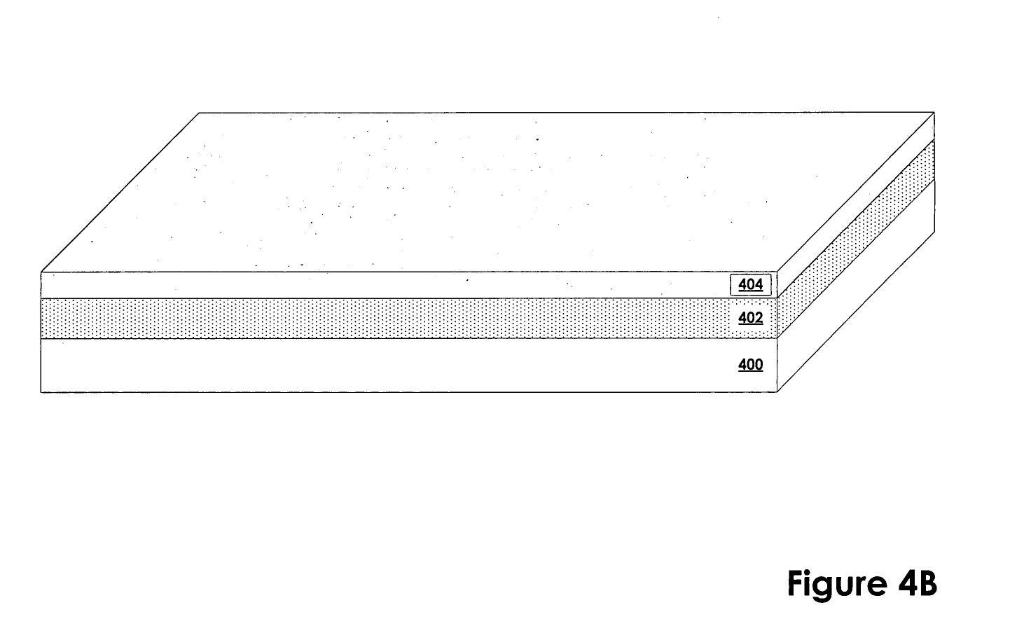

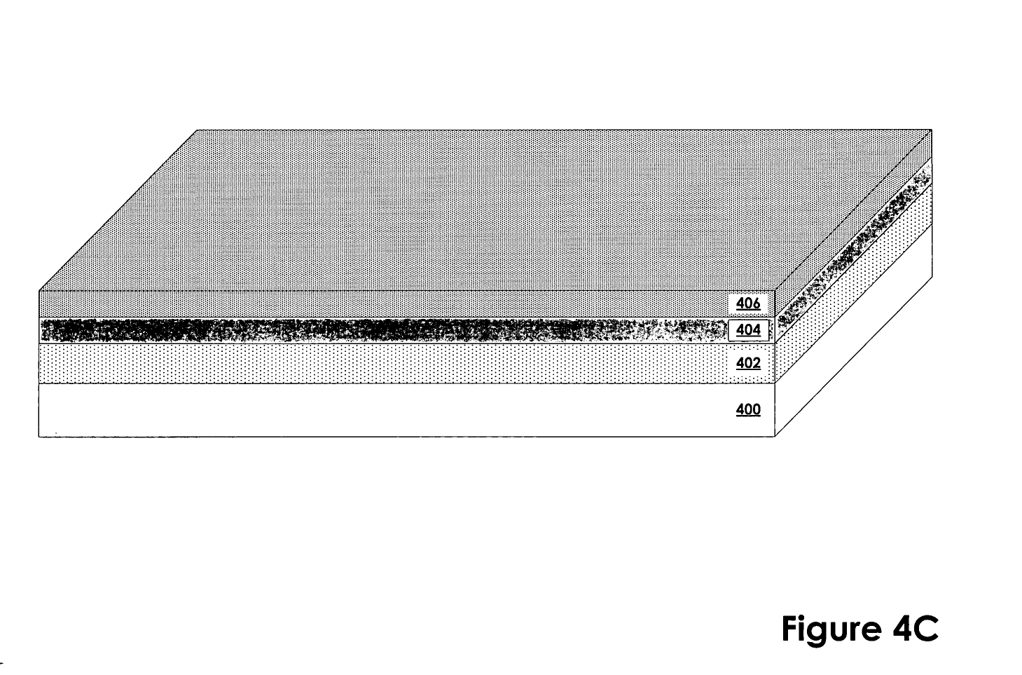

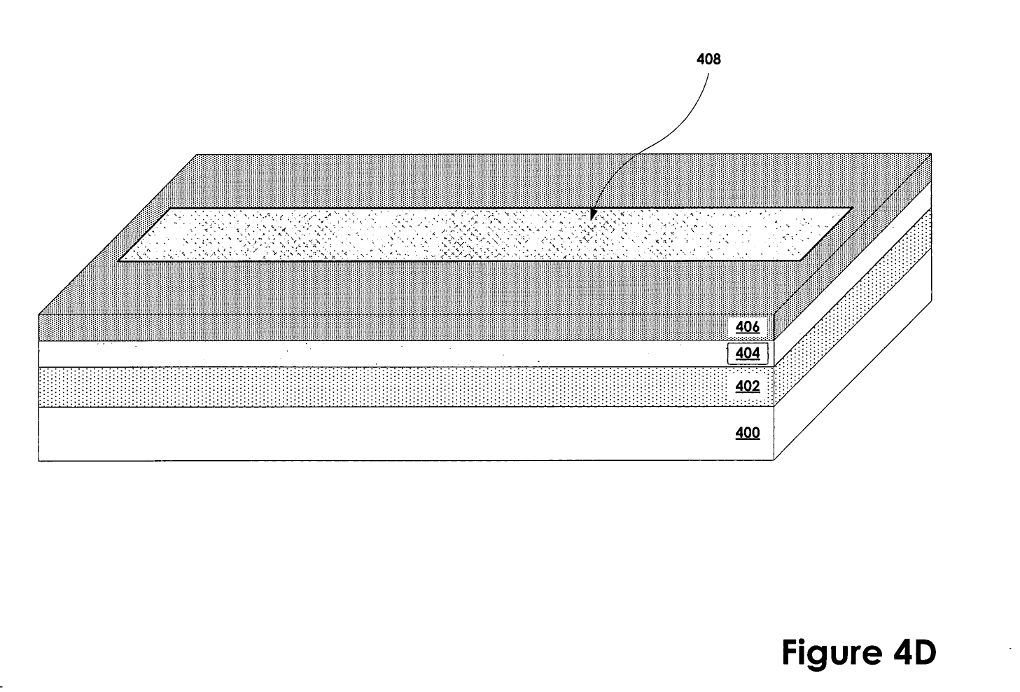

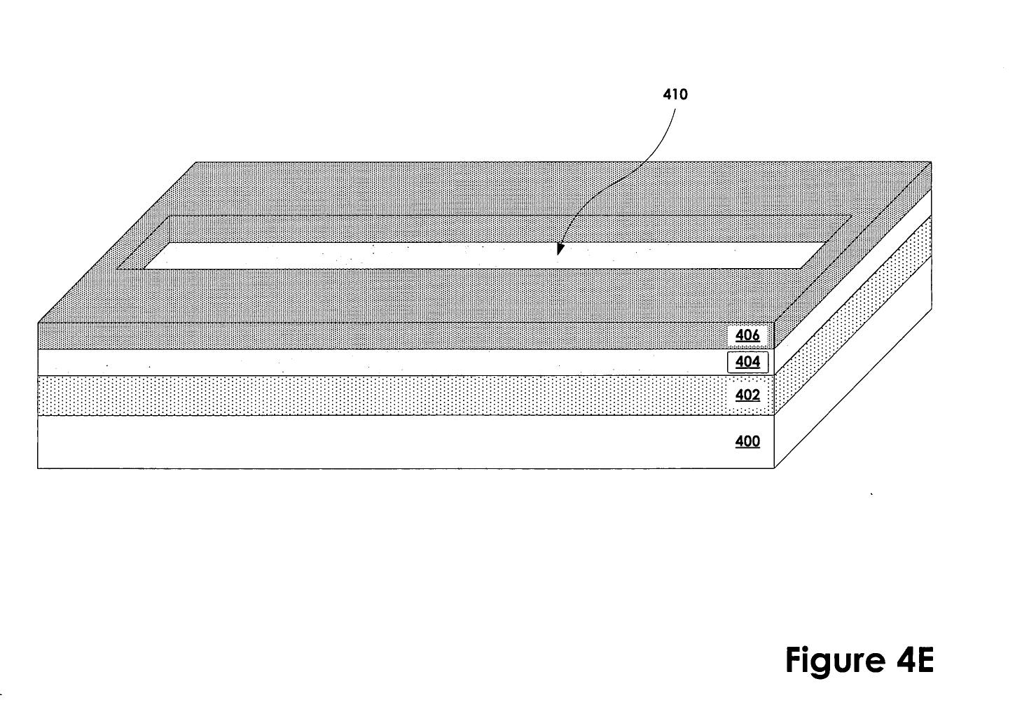

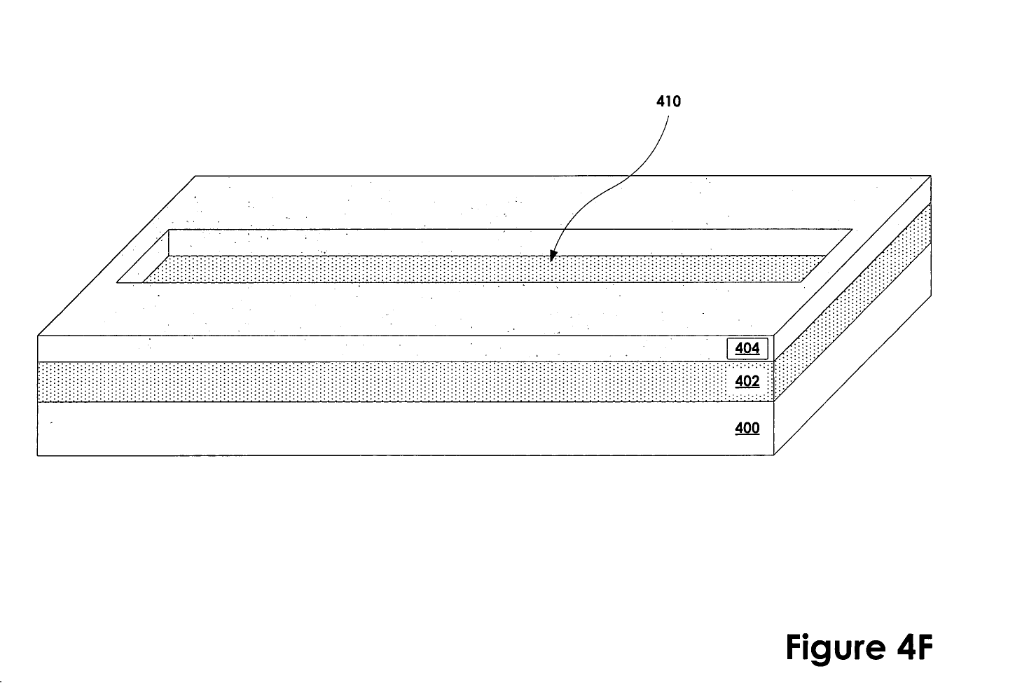

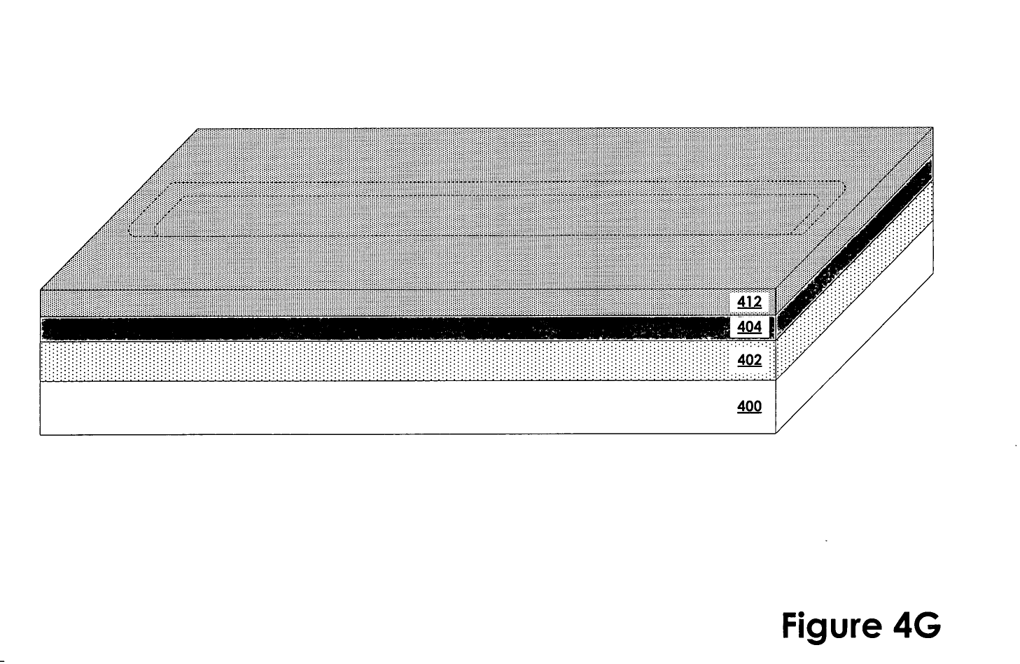

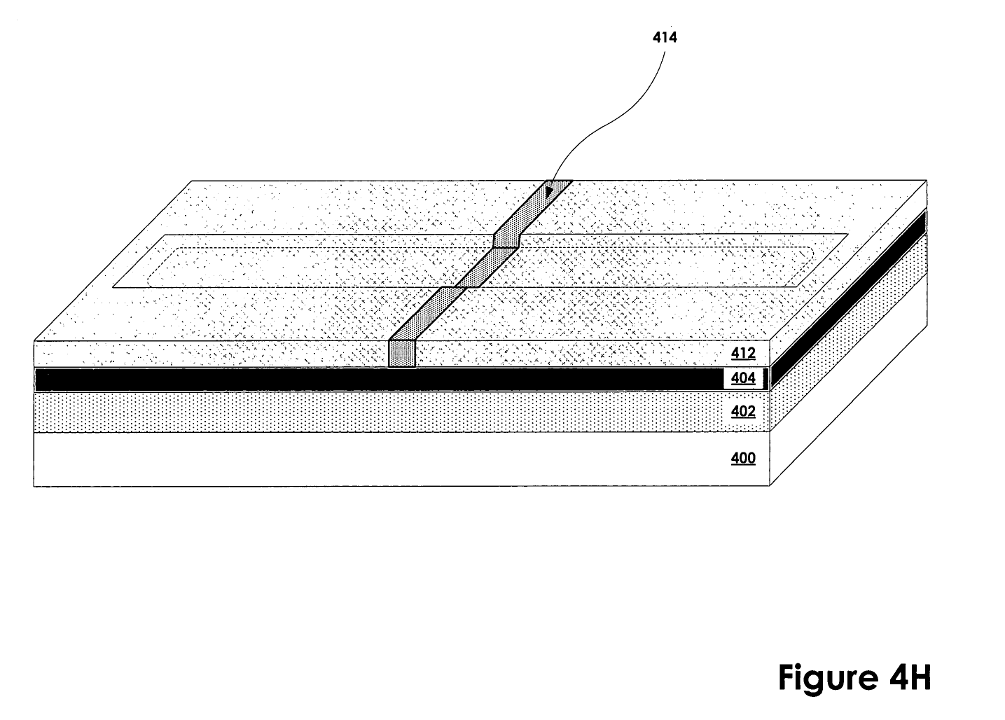

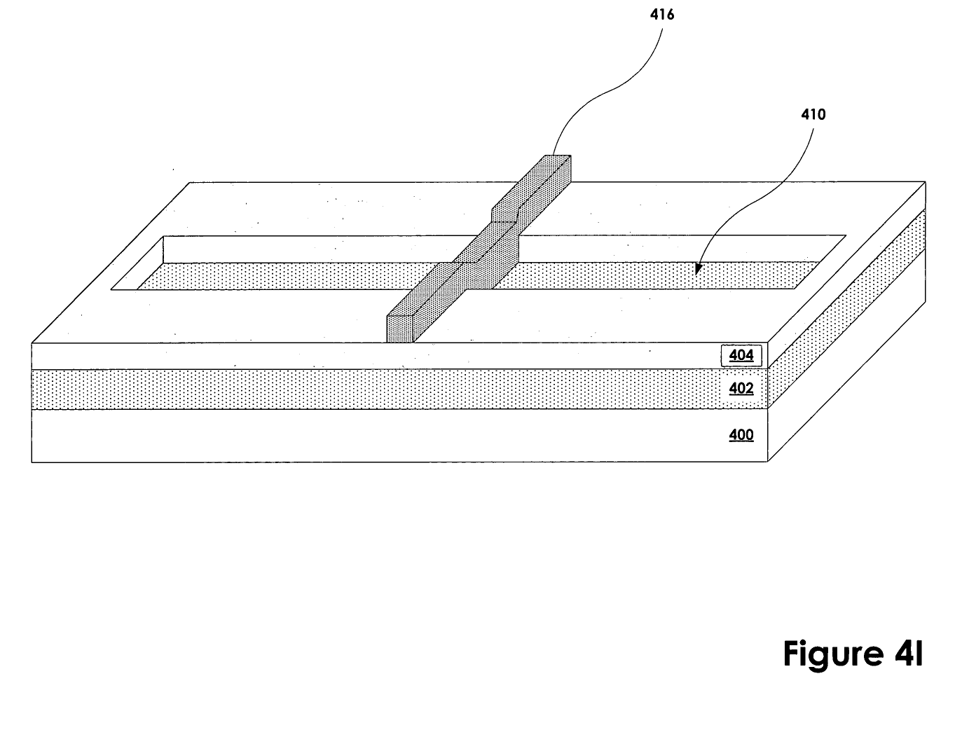

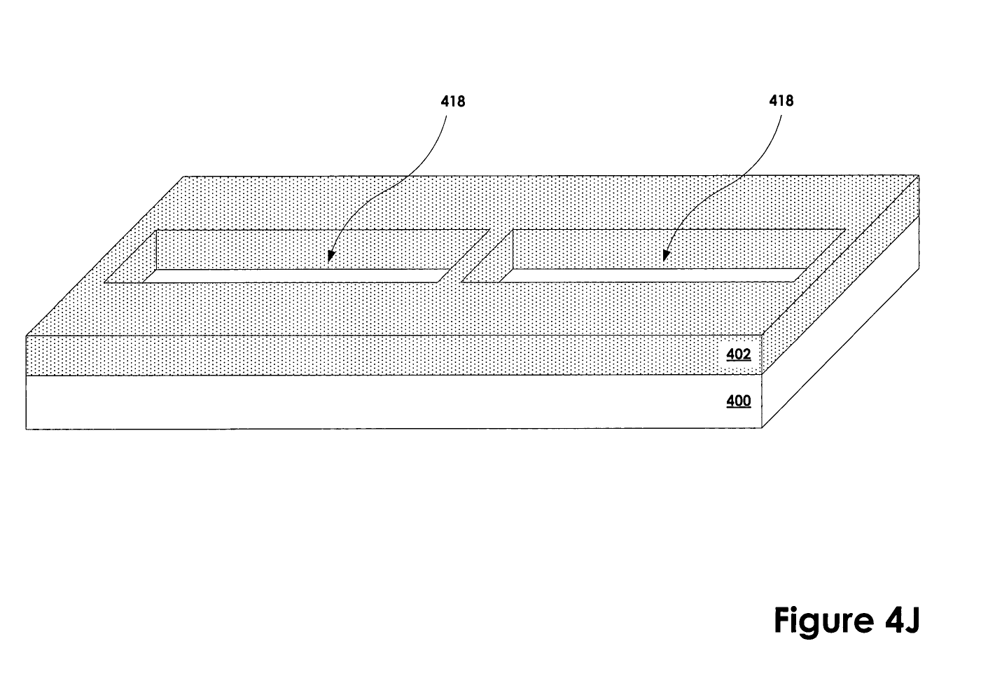

FIG. 3 is a method 300 of forming trenches in a dielectric layer with tight end-to-end spacing in accordance with an implementation of the invention. FIGS. 4A through 4J illustrate structures that are formed while carrying out the method 300. For ease of explanation, the structures shown in FIGS. 4A through 4J will be referenced during the discussion of the method 300 below.

Turning to FIG. 3, the method 300 for forming trenches with tight end-to-end spacing in accordance with the invention begins by providing a substrate having a dielectric layer formed thereon (process 302 of FIG. 3). FIG. 4A illustrates a substrate 400 that includes a dielectric layer 402. It is within this dielectric layer 402 that two trenches with tight end-to-end spacing are to be formed in accordance with methods of the invention.

The substrate 400 may be a semiconductor wafer. In implementations of the invention, the substrate 400 may be formed using bulk silicon or a silicon-on-insulator substructure. In other implementations, the substrate 400 may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate 400 may be formed are described here, any material that may serve as a foundation upon which a semiconductor device may be built falls within the spirit and scope of the present invention.

The dielectric layer 402 formed on the substrate 400 provides insulation between electrical components, such as the two trenches to be formed. As semiconductor device dimensions decrease, electrical components such as interconnects must be formed closer together. This unfortunately increases the capacitance between components with the resulting interference and crosstalk degrading device performance. To address this issue, dielectric materials with lower dielectric constants (i.e., low-k dielectric materials) are used to provide better insulation between electrical components. In accordance with the invention, the dielectric layer 402 may be formed using any known suitable dielectric materials, including but not limited to oxides such as silicon dioxide (SiO₂) and carbon doped oxide (CDO), silicon nitride, organic polymers such as perfluorocyclobutane (PFCB), or fluorosilicate glass (FSG).

Returning to FIG. 3, a deposition process forms a hard-mask layer over the dielectric layer (304). FIG. 4B illustrates a hard-mask layer 404 that is formed atop the dielectric layer 402. The hard-mask layer 404 may be formed from conventional materials used in semiconductor processing for hard-masks, including but not limited to titanium, titanium nitride, tungsten, silicon nitride, silicon oxynitride, silicon carbide, suitable metals, and suitable dielectric materials. Any material that has a relatively high etch selectivity to the chemistries used to etch the underlying dielectric layer may be used. Deposition processes that may be used to form the hard-mask layer include, but are not limited to, physical vapor deposition (PVD), chemical vapor deposition (CVD), plasma-enhanced CVD (PECVD), atomic layer deposition (ALD), spin-on deposition (SOD), sputter deposition, and epitaxial growth.

After the hard-mask layer is deposited, a deposition process forms a photoresist layer on the hard-mask layer (306 of FIG. 3). FIG. 4C illustrates a photoresist layer 406 that is formed atop the hard-mask layer 404. The photoresist layer 406 is formed using a conventional photoresist material and may be deposited using a process such as SOD. Other deposition processes appropriate for the chosen photoresist material may be used as well.

Next, a photolithography process patterns an extended trench into the photoresist layer. This is a multi-step process that includes exposing the photoresist layer to radiation, such as ultraviolet (UV) radiation, extreme ultraviolet (EUV) radiation, or an electron beam, through an optical mask to transfer a pattern for the extended trench onto the photoresist layer (308 of FIG. 3). The optical mask contains a pattern for the extended trench.

FIG. 4D illustrates the photoresist layer 406 after it has been exposed to radiation through an optical mask to define an extended trench pattern 408. The photoresist material within the extended trench pattern 408 is susceptible to removal by a developer solution. As described above, the extended trench pattern 408 is contained on an optical mask and then transferred to the photoresist layer 406 by way of the radiation exposure. In some implementations of the invention, the layout of the optical mask initially includes patterns for the extended trenches. In alternate implementations, the layout of the optical mask includes trenches with tight end-to-end spacing, and processes are carried out to convert such trenches into extended trenches before the layout to printed on the optical mask. For instance, computer software used for designing the layout of an optical mask may be adapted to automatically convert trenches with tight end-to-end spacing into an extended trench. A predetermined minimum threshold for the end-to-end spacing may be used by the software when analyzing the optical mask layout and deciding which trenches to convert into extended trenches.

The photolithography process also includes developing the photoresist layer to remove portions of the photoresist layer and form an extended trench in the photoresist layer (310 of FIG. 3). Conventional developer solutions appropriate for the specific photoresist material used may be applied to remove the photoresist material from within the extended trench pattern 408. For instance, one commonly used developer solution is tetramethyl ammonium hydroxide (TMAH). FIG. 4E illustrates the photoresist layer 406 after development. An extended trench 410 has been formed in the developed photoresist layer 406 based on the extended trench pattern 408.

The developed photoresist layer now functions as a mask to transfer the extended trench into the hard-mask layer. Accordingly, an etching process removes portions of the hard-mask layer that are left exposed by the developed photoresist mask (312 of FIG. 3). FIG. 4F illustrates the hard-mask layer 404 after the etching process is complete and after the developed photoresist layer 406 has been removed. The extended trench 410 is now formed in the hard-mask layer 404. Conventional etching processes may be used that are appropriate for the particular material chosen for the hard-mask layer 404. For instance, in some implementations, chloride containing chemistries, SF₆, or CₓH_{y}F_{z} chemistries may be used to etch the hard-mask layer 404 depending on the specific material used to form the hard-mask layer 404. Conventional processes may also be used to remove any remaining photoresist material. For instance, the photoresist and post-etch polymer residues may be removed using oxygen or forming gas based plasma ashes, or chemical cleans that dissolve the photoresist and polymers, or a combination thereof.

Next, a second deposition process forms a second photoresist layer on the hard-mask layer and on exposed portions of the dielectric layer (314 of FIG. 3). FIG. 4G illustrates a second photoresist layer 412 that is formed atop the hard-mask layer 404. Like the photoresist layer 406, the second photoresist layer 412 is formed using a conventional photoresist material and may be deposited using a process such as SOD. Other deposition processes appropriate for the chosen photoresist material may be used as well. A portion of the second photoresist layer 412 may be depressed due to the underlying extended trench 410, as shown in FIG. 4G. In some implementations, if adequate etch selectivity to the hard-mask layer 404 can be achieved for the dielectric layer 402 etch, the hard-mask layer 404 can be relatively thin which would minimize the depression of the second photoresist layer 412 within the extended trench 410.

Next, a second photolithography process patterns a resist line into the second photoresist layer. Again, this is a multi-step process that includes exposing the second photoresist layer to radiation, such as UV, EUV, or electron beam, through a second optical mask to transfer a pattern for the resist line onto the second photoresist layer (316 of FIG. 3). The second optical mask contains a pattern for the resist line.

FIG. 4H illustrates the second photoresist layer 412 after it has been exposed to radiation through the second optical mask to define a resist line pattern 414. The photoresist material outside of the resist line pattern 414 is susceptible to removal by a developer solution. As described above, the resist line pattern 414 is contained on a second optical mask and then transferred to the second photoresist layer 412 by way of the radiation exposure.

The second photolithography process also includes developing the second photoresist layer to remove portions of the second photoresist layer and form a resist line within the extended trench (318 of FIG. 3). Conventional developer solutions appropriate for the specific photoresist material may be applied to remove the photoresist material from around the resist line pattern 414. Again, a developer solution such as TMAH may be used. FIG. 4I illustrates a resist line 416 that has been formed after development of the second photoresist layer 412. The resist line 416 lies within the extended trench 410 and may also lie atop portions of the hard-mask layer 404.

As shown, the resist line 416 may be a three-dimensional structure, for instance a prism with square or rectangular ends, that intersects the extended trench 410 to separate the extended trench 410 into two independent trenches. The resist line 416 may be likened to a dam within the extended trench 410 that separates the trench 410 into two sections. The width of the resist line 416 substantially corresponds to the end-to-end distance between the two trenches that are to be formed in the dielectric layer 402. Accordingly, the width of the resist line 416 may be chosen and patterned based on the desired end-to-end distance for a particular application.

Combined, the hard-mask layer and the resist line now function as a mask that defines two separate trenches on the dielectric layer, where the end-to-end spacing between the two trenches is defined by the width of the resist line. Accordingly, an etching process removes portions of the dielectric layer that are left exposed by the hard-mask layer and the resist line (320 of FIG. 3). Conventional etching processes appropriate for dielectric layers may be used. For instance, if the dielectric layer is silicon dioxide or carbon doped oxide, a CₓF_{y}H_{z} etch chemistry may be used.

FIG. 4J illustrates the dielectric layer 402 after the etching process is complete and after the hard-mask layer 404 and the resist line 416 have been removed. The resist line 416 may be removed using conventional removal techniques for photoresist masks. Likewise, the hard-mask layer 404 may be removed using conventional methods for removing hard-masks, for instance, using the same process that was used earlier to etch the hard-mask layer 404.

As shown, the etching process on the dielectric layer results in the formation of two trenches 418 that have a tight end-to-end spacing. This type of spacing cannot be achieved with conventional photolithography processes due to their inherent resolution limitations. The methods of the invention therefore allow the conventional two-dimensional end-to-end resolution problem that is inherently difficult to overcome to be replaced by a one-dimensional patterning scheme where the width of the resist line essentially determines the minimum end-to-end separation. Because the one-dimensional minimum line patterning is inherently easier and more controllable, the methods of the invention can deliver improved end-to-end features. As such, a process has been disclosed for forming trenches in a dielectric layer with tight end-to-end spacing using a dual patterning process. The tight end-to-end separation distance enables circuits to be formed that have smaller dimensions, thereby allowing circuit density to increase.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate having a dielectric layer;
depositing a hard-mask layer on the dielectric layer;
patterning the hard-mask layer to form an extended trench in the hard-mask layer;
depositing a photoresist layer on the hard-mask layer;
patterning the photoresist layer to form a resist line, wherein the resist line intersects the extended trench; and
patterning the dielectric layer to form at least two trenches in the dielectric layer, wherein the hard-mask layer and the resist line function as a mask.

2. The method of claim 1, wherein the substrate comprises a semiconductor substrate.

3. The method of claim 2, wherein the semiconductor substrate comprises at least one of silicon, SOI, germanium, indium antimonide, lead telluride, indium arsenide, indium phosphide, gallium arsenide, and gallium antimonide.

4. The method of claim 1, wherein the dielectric layer comprises at least one of silicon dioxide, carbon doped oxide, silicon nitride, perfluorocyclobutane, or fluorosilicate glass.

5. The method of claim 1, wherein the hard-mask layer comprises a material that has a relatively high etch selectivity to the chemistry used to pattern the dielectric layer.

6. The method of claim 1, wherein the patterning of the hard-mask layer comprises:
depositing a second photoresist layer on the hard-mask layer;
exposing the second photoresist layer to radiation through an optical mask to pattern an extended trench in the second photoresist layer;
developing the second photoresist layer to form an extended trench in the second photoresist layer; and
etching the hard-mask layer, wherein the developed second photoresist layer functions as a mask.

7. The method of claim 1, wherein the patterning of the photoresist layer comprises:
exposing the photoresist layer to radiation through an optical mask to pattern a resist line in the photoresist layer; and
developing the photoresist layer to form a resist line.

8. The method of claim 1, wherein the patterning of the dielectric layer is performed using a CₓF_{y}H_{z} etch chemistry.

9. The method of claim 1, wherein an end-to-end separation distance between the two trenches formed in the dielectric layer substantially corresponds to a width of the resist line.

10. A method comprising:
providing a substrate having a dielectric layer;
depositing a hard-mask layer on the dielectric layer;
depositing a first photoresist layer on the hard-mask layer;
exposing the first photoresist layer to radiation through a first optical mask, wherein the first optical mask includes a pattern for an extended trench;
developing the first photoresist layer to form an extended trench in the first photoresist layer;
etching the hard-mask layer using the developed first photoresist layer as a mask, wherein an extended trench is formed in the hard-mask layer;
depositing a second photoresist layer on the hard-mask layer;
exposing the second photoresist layer to radiation through a second optical mask, wherein the second optical mask includes a pattern for a resist line that intersects the extended trench in the hard-mask layer;
developing the second photoresist layer to form a resist line that intersects the extended trench in the hard-mask layer, wherein the resist line divides the extended trench into two separate trenches;
etching the dielectric layer using the hard-mask layer and the resist line as a mask, wherein two trenches are formed in the dielectric layer;
removing the resist line; and
removing the hard-mask layer.

11. The method of claim 10, wherein the substrate comprises a semiconductor substrate.

12. The method of claim 11, wherein the semiconductor substrate comprises at least one of silicon, SOI, germanium, indium antimonide, lead telluride, indium arsenide, indium phosphide, gallium arsenide, and gallium antimonide.

13. The method of claim 10, wherein the dielectric layer comprises at least one of silicon dioxide, carbon doped oxide, silicon nitride, perfluorocyclobutane, or fluorosilicate glass.

14. The method of claim 10, wherein the hard-mask layer comprises titanium, titanium nitride, tungsten, silicon nitride, silicon oxynitride, or silicon carbide.

15. The method of claim 10, wherein the hard-mask layer is deposited using a CVD process, a PVD process, an ALD process, or an SOD process.

16. The method of claim 10, wherein the first photoresist layer is deposited using an SOD process.

17. The method of claim 10, wherein the radiation comprises UV, EUV, or electron beam.

18. The method of claim 10, wherein the developing of the first photoresist layer comprises applying a developer solution to the first photoresist layer to remove portions of the photoresist layer and form an extended trench within the first photoresist layer.

19. The method of claim 18, wherein the developer solution comprises TMAH.

20. The method of claim 10, wherein the etching of the hard-mask layer comprises using a chloride containing chemistry, an SF₆ chemistry, or a CₓH_{y}F_{z} chemistry to etch the hard-mask layer.

21. The method of claim 10, wherein the second photoresist layer is deposited using an SOD process.

22. The method of claim 10, wherein the developing of the second photoresist layer comprises applying a developer solution to the second photoresist layer to remove portions of the photoresist layer and form a resist line within the extended trench in the hard-mask layer.

23. The method of claim 22, wherein the developer solution comprises TMAH.

24. The method of claim 10, wherein the etching of the dielectric layer is performed using a CₓF_{y}H_{z} etch chemistry.

25. The method of claim 10, wherein the removing of the resist line comprises using an oxygen based plasma ash, a forming gas plasma ash, or a chemical clean to remove the resist line.

26. The method of claim 10, wherein the removing the hard-mask layer comprises using a chloride containing chemistry, an SF₆ chemistry, or a CₓH_{y}F_{z} chemistry to etch the hard-mask layer.

27. The method of claim 10, wherein an end-to-end separation distance between the two trenches formed in the dielectric layer substantially corresponds to a width of the resist line.
